(19) United States
(12) Patent Application Publication
(10) Pub. No.: US 2025/0299740 A1
(43) Pub. Date: Sep. 25, 2025

(54) MEMORY INCLUDING MULTIPLE PLANES

(71) Applicant: SK hynix Inc., Icheon-si Gyeonggi-do (KR)

(72) Inventor: Seung Hyun CHUNG, Icheon-si Gyeonggi-do (KR)

(73) Assignee: SK hynix Inc., Icheon-si Gyeonggi-do (KR)

(21) Appl. No.: 18/740,773

(22) Filed: Jun. 12, 2024

(30) Foreign Application Priority Data
Mar. 21, 2024 (KR) 10-2024-0039089

(51) Int. Cl. G11C 16/10; G11C 16/08; G11C 16/26

(52) U.S. Cl. CPC G11C 16/102; G11C 16/08; G11C 16/26

(57) ABSTRACT

Disclosed is a memory including a plurality of planes, and a plurality of microcontrollers, and during a specific operation of a selected plane, among the plurality of planes, at least two microcontrollers, among the plurality of microcontrollers, perform distributed execution of control operations on the selected plane.

### CROSS-REFERENCE TO RELATED APPLICATION(S)

The present application claims priority under 35 U.S.C. § 119(a) to Korean Patent Application No. 10-2024-0039089, filed in the Korean Intellectual Property Office on Mar. 21, 2024, the disclosure of which application is incorporated herein by reference in its entirety.

### BACKGROUND

### 1. Technical Field

Various embodiments of the present disclosure relate to a memory, and more particularly, to a memory including multiple planes.

### 2. Related Art

A memory is largely classified into a volatile memory and a non-volatile memory. The volatile memory is fast at reading and writing data but loses data stored therein when the supply of external power is interrupted. On the other hand, the non-volatile memory retains data stored therein even when the supply of external power is interrupted. Therefore, the non-volatile memory is used to remember content that has to be retained regardless of whether power is being supplied or not.

The non-volatile memory includes memory cells and may perform a program operation to store data in the memory cells, a read operation to output stored data, and an erase operation to delete the stored data. Meanwhile, the non-volatile memory may include multiple planes. Each of the planes, each being physically independent data storage units, may store separate data and may operate independently.

### SUMMARY

In accordance with an embodiment, a memory may include: a plurality of planes; and a plurality of microcontrollers, wherein, during a specific operation of a selected plane, among the plurality of planes, at least two microcontrollers, among the plurality of microcontrollers, may perform distributed execution of control operations on the selected plane.

In accordance with an embodiment, a memory may include: a plurality of planes; and a plurality of microcontrollers, wherein each of the plurality of planes may include: a cell array; a voltage generation circuit; a row circuit suitable for controlling row lines of the cell array by using voltages generated by the voltage generation circuit; and a page buffer array suitable for sensing data by using column lines of the cell array, and controlling the column lines of the cell array to program data into the cell array, wherein, during a specific operation of a selected plane, among the plurality of planes, at least two microcontrollers, among the plurality of microcontrollers, may perform distributed control over the voltage generation circuit, row circuit and page buffer array of the selected plane.

### BRIEF DESCRIPTION OF THE DRAWINGS

FIG. 1 is a block diagram illustrating a memory in accordance with an embodiment.

FIG. 2 is a block diagram illustrating a plane in accordance with an embodiment.

FIG. 3 is a diagram illustrating control operations of a microcontroller during a program operation of a plane as illustrated in FIG. 1.

FIG. 4 is a block diagram illustrating a memory in accordance with an embodiment.

FIG. 5 is a diagram illustrating control operations of microcontrollers during a program operation of a plane as illustrated in FIG. 4.

### DETAILED DESCRIPTION

Various embodiments of the present disclosure are directed to technology to improve performance of a memory.

According to embodiments of the present disclosure, it is possible to improve performance of a memory.

Hereinafter, various embodiments according to the technical spirit of the present disclosure are described below with reference to the accompanying drawings.

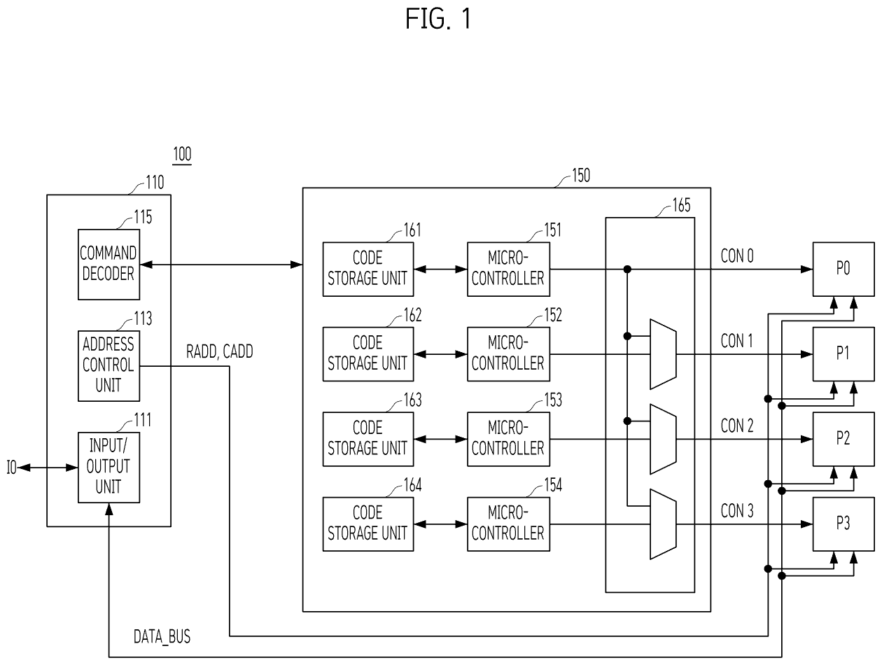

FIG. 1 is a block diagram illustrating a memory 100 in accordance with an embodiment.

Referring to FIG. 1, the memory 100 may include an interface block 110, a logic block 150, and planes P0 to P3.

The interface block 110, which is a block that provides an interface between the memory 100 and a memory controller external to the memory 100, may include an input/output unit 111, an address control unit 113, and a command decoder 115.

The input/output unit 111 may communicate with the memory controller through input/output lines IO. The input/output unit 111 may transfer a command received from the input/output lines IO to the command decoder 115 and may transfer an address received from the input/output lines IO to the address control unit 113. In addition, the input/output unit 111 may receive data to be programmed into the planes P0 to P3 from the input/output lines IO or may transmit data read from the planes P0 to P3 to the input/output lines IO. A data bus DATA_BUS, illustrated in the drawing, may be a bus for data transmission between the input/output unit 111 and the planes P0 to P3.

The address control unit 113 may use the address received through the input/output unit 111 to select a plane, among the planes P0 to P3, on which to perform an operation and may generate a row address RADD and a column address CADD to select memory cells to be accessed within the selected plane. Information on the selected plane may be transferred to the command decoder 115.

The command decoder 115 may decode the command received through the input/output unit 111 and may determine an operation instructed by the memory controller to the memory 100. Information decoded by the command decoder 115 may be transferred to the logic block 150.

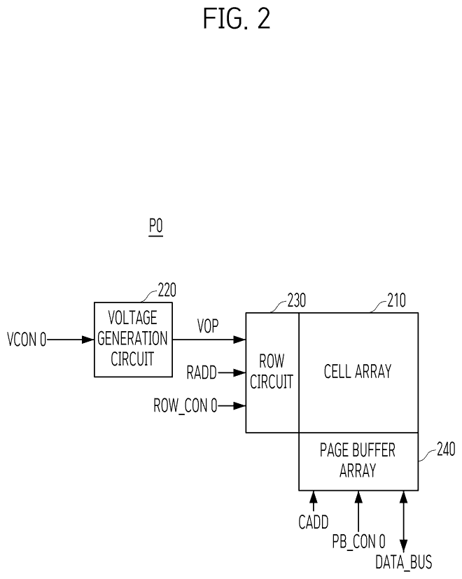

Each of the planes P0 to P3 may be an independent storage unit. Each of the planes P0 to P3 may store separate data therein and may operate independently. FIG. 2 is a diagram illustrating a configuration of the plane P0 in accordance with an embodiment. Planes P1 to P3 may also be configured in substantially the same manner as the plane P0, illustrated in FIG. 2. Referring to FIG. 2, the plane P0 may include a cell array 210, a voltage generation circuit 220, a row circuit 230, and a page buffer array 240.

The cell array 210 may include multiple memory cells. The cell array 210 may be divided into multiple memory blocks, and each of the memory blocks may be divided into multiple pages. Herein, program and read operations may be performed in units of pages, and an erase operation may be performed in units of memory blocks.

The voltage generation circuit 220 may generate various operating voltages VOP. For example, the voltage generation circuit 220 may generate various voltages used for program, read, verification, and erase operations. Voltage control signals V_CON0 may represent signals that control an operation of the voltage generation circuit 220.

The row circuit 230 may control row lines of the cell array 210 in response to row control signals ROW_CON0 and the row address RADD. The row lines may include drain select lines, source select lines, and word lines. The row control signals ROW_CON0 may represent signals that control an operation of the row circuit 230.

In response to page buffer control signals PB_CON0 and the column address CADD, the page buffer array 240 may sense data of the cell array 210 by using column lines of the cell array 210 and may control the column lines to program data into and erase data from the cell array 210. The column lines may include bit lines. The page buffer control signals PB_CON0 may represent signals that control an operation of the page buffer array 240. During the program operation, data may be transferred from the data bus DATA_BUS to the page buffer array 240, and during the read operation, data may be transferred from the page buffer array 240 to the data bus DATA_BUS.

Referring back to FIG. 1, the logic block 150 may control operations of the planes P0 to P3 according to a decoding result of the command decoder 115. The logic block 150 may include microcontrollers 151 to 154, code storage units 161 to 164, and a multiplexing circuit 165.

The microcontroller 151 may control the program, erase, and (normal) read operations of the planes P0 to P3. Codes necessary for the control operations of the microcontroller 151 may be stored in the code storage unit 161. That is, the microcontroller 151 may control the operations of the planes P0 to P3 while the codes stored in the code storage unit 161 are executed. The code storage unit 161 may be a read only memory (ROM).

In a multi-plane operation, the microcontrollers 152 to 154 may be used for a parallel operation of the planes P0 to P3. When the planes P0 to P3 operate in parallel, for example, during a multi-plane interleaved read operation, the microcontroller 151 may control the plane P0, the microcontroller 152 may control the plane P1, the microcontroller 153 may control the plane P2, and the microcontroller 154 may control the plane P3. Codes necessary for control operations of the microcontrollers 152 to 154 may be stored in the code storage units 162 to 164, respectively. Because the microcontroller 151 is used for both the single plane operation and the multi-plane operation, codes for controlling the single plane operation and codes for controlling the multi-plane operation may be stored in the code storage unit 161. Because the microcontrollers 152 to 154 are used only for the multi-plane operation, only codes for controlling the multi-plane operation may be stored in the code storage units 162 to 164. That is, less codes may be stored in one of the code storage units 162 to 164 than in the code storage unit 161.

The multiplexing circuit 165 may control a connection between the microcontrollers 151 to 154 and the planes P0 to P3. During the single plane operation in which one selected plane, among the planes P0 to P3, operates, the microcontroller 151 may control the selected plane. For example, during the program operation of the plane P1, the microcontroller 151 may generate control signals V_CON1, ROW_CON1, and PB_CON1 (indicated as CON1 in FIG. 1) of the plane P1, and during the program operation of the plane P3, the microcontroller 151 may generate control signals V_CON3, ROW_CON3, and PB_CON3 (indicated as CON3 in FIG. 1) of the plane P3. On the other hand, during the multi-plane operation in which the planes P0 to P3 operate in parallel, the microcontrollers 151 to 154 may control the planes P0 to P3, respectively. For example, during the multi-plane interleaved read operation of the planes P0 to P3, the microcontroller 151 may generate control signals V_CON0, ROW_CON0, and PB_CON0 (indicated as CON0 in FIG. 1) of the plane P0, the microcontroller 152 may generate control signals V_CON1, ROW_CON1, and PB_CON1 (indicated as CON1 in FIG. 1) of the plane P1, the microcontroller 153 may generate control signals V_CON2, ROW_CON2, and PB_CON2 (indicated as CON2 in FIG. 1) of the plane P2, and the microcontroller 154 may generate control signals V_CON3, ROW_CON3, and PB_CON3 (indicated as CON3 in FIG. 1) of the plane P3.

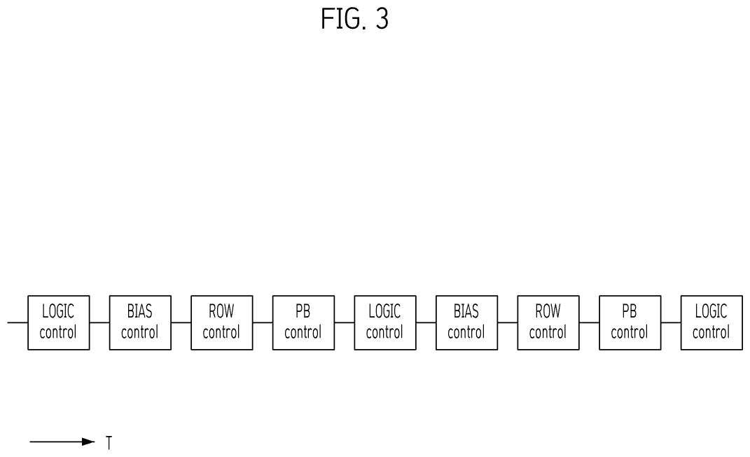

FIG. 3 is a diagram illustrating the control operations of the

microcontroller 151 during the program operation of the plane P1 as illustrated in FIG. 1.

Referring to FIG. 3, as time T elapses from left to right, a logic control operation LOGIC control of the microcontroller 151, a bias control operation BIAS control of the microcontroller 151, a control operation ROW control of a row circuit, a page buffer control operation PB control of a row circuit, a logic control operation LOGIC control of a row circuit, a bias control operation BIAS control of a row circuit, a control operation ROW control of a row circuit, a page buffer control operation PB control of a row circuit, and a logic control operation LOGIC control of a row circuit may be sequentially performed. In other words, the microcontroller 151 may sequentially perform one operation at a time.

Herein, the logic control operation LOGIC control may be

an operation that controls a flow of the entire operation, and the bias control operation BIAS control may be an operation that generates the voltage control signals V_CON1 of the plane P1. In addition, the control operation ROW control of the row circuit may be an operation that generates the row control signals ROW_CON1 of the plane P1, and the page buffer control operation PB control may be an operation that generates the page buffer control signals PB_CON1 of the plane P1.

Even when the planes P0 to P3 operate in parallel, the planes P0 to P3 may be respectively controlled by the microcontrollers 151 to 154 in the same manner as illustrated in FIG. 3.

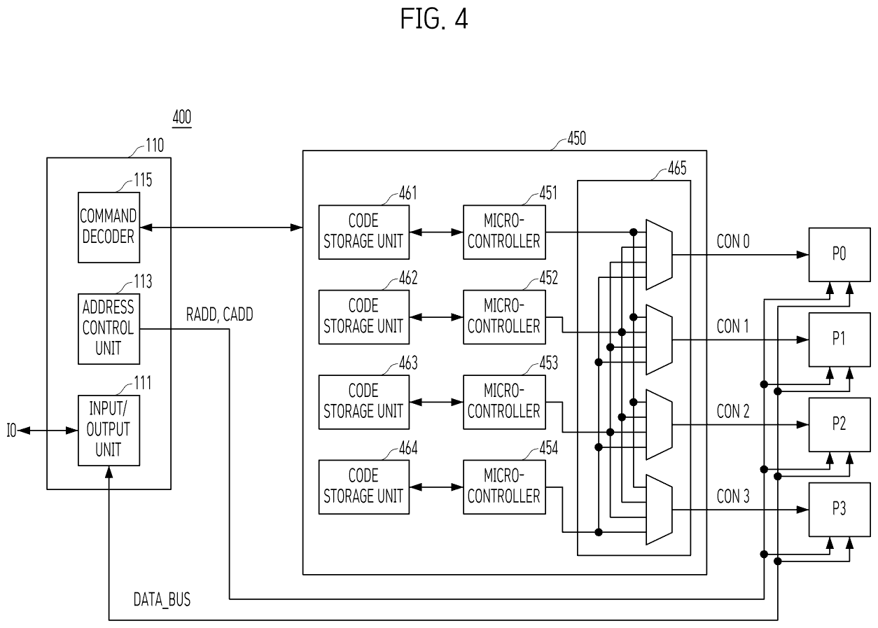

FIG. 4 is a block diagram illustrating a memory 400 in accordance with an embodiment.

Referring to FIG. 4, the memory 400 may include an interface block 110, a logic block 450, and planes P0 to P3. The logic block 450 of the memory 400 may be designed differently from the logic block 150 of the memory 100.

The logic block 450 may control operations of the planes P0 to P3 according to a decoding result of a command decoder 115. The logic block 450 may include microcontrollers 451 to 454, code storage units 461 to 464, and a multiplexing circuit 465.

The microcontrollers 451 to 454 may control program, erase, and (normal) read operations of the planes P0 to P3. In addition, the microcontrollers 451 to 454 may respectively control the planes P0 to P3 to operate in parallel.

During a single plane operation in which one selected plane, among the planes P0 to P3, operates, the duties of executing the different control operations on the selected plane may be distributed (i.e., distributed execution) amongst the microcontrollers 451 to 454. For example, during a program operation of the plane P2, the microcontroller 451 may perform a logic control operation on the plane P2, the microcontroller 452 may perform a bias control operation on the plane P2, the microcontroller 453 may perform a control operation on a row circuit of the plane P2, and the microcontroller 454 may perform a page buffer control operation on the plane P2. Because the microcontrollers 451 to 454 perform a distributed execution of the control operations on the plane P2 in parallel, operational performance of the plane P2 may be further improved.

When the planes P0 to P3 operate in parallel, for example, during a multi-plane interleaved read operation, the microcontrollers 451 to 454 may control operations of their respective planes among the planes P0 to P3. For example, during the multi-plane interleaved read operation of the planes P0 to P3, the microcontroller 451 may control the plane P0, the microcontroller 452 may control the plane P1, the microcontroller 453 may control the plane P2, and the microcontroller 454 may control the plane P3.

Codes necessary for control operations of the microcontrollers 451 to 454 may be stored in the code storage units 461 to 464. Because the microcontrollers 451 to 454 are used both for the single plane operation and the multi-plane operation, codes for distributed control (i.e., control to perform a distributed execution) of the single plane operation and control of the multi-plane operation may be stored in the code storage units 461 to 464.

The multiplexing circuit 465 may control a connection between the microcontrollers 451 to 454 and the planes P0 to P3. During the single plane operation in which one selected plane, among the planes P0 to P3, operates, the microcontrollers 451 to 454 may perform a distributed execution of control operations on the selected plane. For example, during the program operation of the plane P3, the microcontroller 452 may generate voltage control signals V_CON3 of the plane P3, the microcontroller 453 may generate row control signals ROW_CON3 of the plane P3, and the microcontroller 454 may generate buffer control signals PB_CON3 of the plane P3. The microcontroller 451 may perform a logic control operation that controls when the microcontrollers 452 to 454 have to generate the control signals V_CON3, ROW_CON3, and PB_CON3, that is, a flow. During the multi-plane operation in which the planes P0 to P3 operate in parallel, the microcontrollers 451 to 454 may control the planes P0 to P3. For example, during the multi-plane interleaved read operation of the planes P0 to P3, the microcontroller 451 may generate control signals V_CON0, ROW_CON0, and PB_CON0 of the plane P0, the microcontroller 452 may generate control signals V_CON1, ROW_CON1, and PB_CON1 of the plane P1, the microcontroller 453 may generate control signals V_CON2, ROW_CON2, and PB_CON2 of the plane P2, and the microcontroller 454 may generate control signals V_CON3, ROW_CON3, and PB_CON3 of the plane P3.

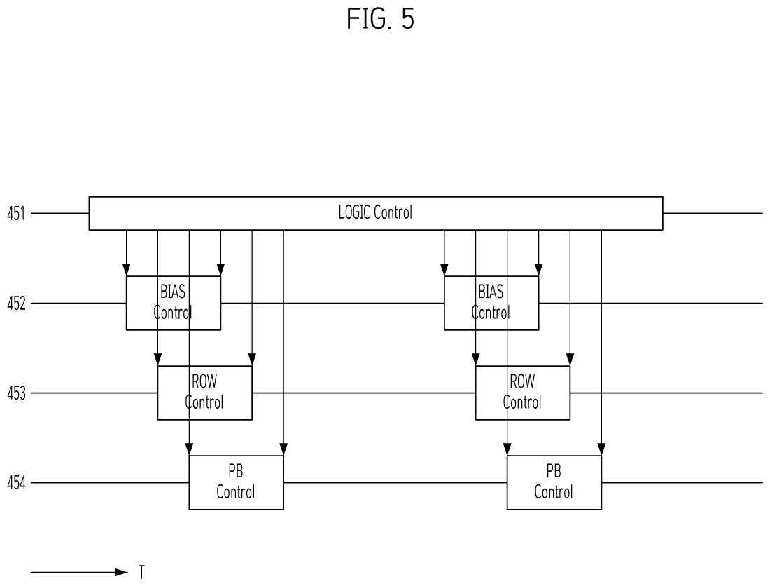

FIG. 5 is a diagram illustrating the control operations of the microcontrollers 451 to 454 during the program operation of the plane P2 as illustrated in FIG. 4.

Referring to FIG. 5, the microcontroller 451 may perform a logic control operation LOGIC Control to control an operational flow of the microcontrollers 452 to 454. That is, the microcontroller 451 may control when the microcontrollers 452 to 454 have to start and end their operations.

The microcontroller 452 may perform a bias control operation BIAS Control to generate the voltage control signals V_CON2 of the plane P2, and the microcontroller 453 may perform a row control operation ROW Control to generate the row control signals ROW_CON2 of the plane P2. Additionally, the microcontroller 454 may perform a page buffer control operation PB Control to generate the page buffer control signals PB_CON2 of the plane P2.

Comparing FIG. 5 with FIG. 3, FIG. 3 shows operations being performed sequentially, one at a time, while FIG. 5 shows several operations being performed in parallel at a time. That is, because the microcontrollers 451 to 454 distribute and perform the control operations on the plane P2, the operation of the plane may be performed more quickly.

Although FIG. 5 illustrates the program operation of the plane P2, the single program operation of another plane and read and erase operations of a single plane may also be distributed and performed by the microcontrollers 451 to 454 in a similar manner as the program operation of the plane P2 as illustrated in FIG. 5, and consequently, it is obvious that performance of the memory 400 may be improved.

While the present disclosure has been illustrated and described with respect to specific embodiment, the disclosed embodiment is provided for the description, and not intended to be restrictive. Further, it is noted that the present disclosure may be achieved in various ways through substitution, change, and modification that fall within the scope of the following claims, as those skilled in the art will recognize in light of the present disclosure.

What is claimed is:

1. A memory comprising:
a plurality of planes; and
a plurality of microcontrollers,
wherein, during a specific operation of a selected plane, among the plurality of planes, at least two microcontrollers, among the plurality of microcontrollers, perform a distributed execution of control operations on the selected plane.

2. The memory of claim 1, wherein the specific operation includes one or more of a program operation, an erase operation, and a read operation.

3. The memory of claim 1, wherein, during a parallel operation of the plurality of planes, the plurality of microcontrollers perform the control operations on the plurality of planes, respectively.

4. The memory of claim 3, wherein the parallel operation includes a multi-plane interleaved read operation.

5. The memory of claim 1, wherein the control operations include:
a bias control operation that controls generation of various operating voltages;
a page buffer control operation that controls a page buffer;
a control operation of a row circuit to control row lines; and
a logic control operation that controls a flow of the bias control operation, page buffer control operation, and control operation of the row circuit.

6. The memory of claim 5, wherein the at least two microcontrollers include first to fourth microcontrollers, and wherein the first microcontroller performs the logic control operation, the second microcontroller performs the bias control operation, the third microcontroller performs the page buffer control operation, and the fourth microcontroller performs the control operation of the row circuit.

7. A memory comprising:
a plurality of planes; and
a plurality of microcontrollers,
wherein each of the plurality of planes includes:
a cell array;
a voltage generation circuit;
a row circuit suitable for controlling row lines of the cell array by using voltages generated by the voltage generation circuit; and
a page buffer array suitable for sensing data by using column lines of the cell array and controlling the column lines of the cell array to program data into the cell array,
wherein, during a specific operation of a selected plane, among the plurality of planes, at least two microcontrollers, among the plurality of microcontrollers, perform distributed control over the voltage generation circuit, row circuit, and page buffer array of the selected plane.

8. The memory of claim 7, wherein the specific operation includes one or more of a program operation, an erase operation, and a read operation.

9. The memory of claim 7, wherein, during a parallel operation of the plurality of planes, the plurality of microcontrollers perform control operations on the plurality of planes, respectively.

10. The memory of claim 9, wherein the parallel operation includes a multi-plane interleaved read operation.

11. The memory of claim 7, wherein the at least two microcontrollers include first to fourth microcontrollers, and
wherein the first microcontroller controls the voltage generation circuit of the selected plane, the second microcontroller controls the row circuit of the selected plane, the third microcontroller controls the page buffer array of the selected plane, and the fourth microcontroller controls an operational flow of the first to third microcontrollers.
